(19) United States
(12) Patent Application Publication
(10) Pub. No.: US 2024/0105833 A1
(43) Pub. Date: Mar. 28, 2024

(54) SEMICONDUCTOR DEVICE

(71) Applicant: FUJI ELECTRIC CO., LTD., Kanagawa (JP)

(72) Inventor: Shinichiro MATSUNAGA, Matsumoto-city (JP)

(21) Appl. No.: 18/357,169

(22) Filed: Jul. 24, 2023

(30) Foreign Application Priority Data
Sep. 26, 2022 (JP) 2022-152779

(51) Int. Cl. H01L 29/78; H01L 29/06; H01L 29/10

(52) U.S. Cl. CPC H01L 29/7813; H01L 29/0684; H01L 29/1095

(57) ABSTRACT

A semiconductor device is provided that includes a semiconductor substrate containing silicon carbide, and a control circuit unit including one or more control elements and in which the one or more control elements each include a control source region provided in the upper surface of the semiconductor substrate, a control drain region provided in the upper surface of the semiconductor substrate and being of a same conductivity type as the control source region, a control base region provided in contact with the control source region and being of a different conductivity type from the control source region, and a control gate trench section provided from the upper surface of the semiconductor substrate to an internal portion of the semiconductor substrate and being in contact with the control base region.

The contents of the following patent application(s) are incorporated herein by reference:

NO. 2022-152779 filed in JP on Sep. 26, 2022

### BACKGROUND

### 1. Technical Field

The present invention relates to a semiconductor device.

### 2. Related Art

Conventionally known power ICs formed in a semiconductor substrate of silicon carbide are provided with a CMOS gate buffer and a vertical MOSFET (see, for example, non-patent document 1). Non-patent Document 1: Mitsuo Okamoto and three others, “First Demonstration of a Monolithic SiC Power IC Integrating a Vertical MOSFET with a CMOS Gate Buffer”, 2021 33rd International Symposium on Power Semiconductor Devices and ICs (ISPSD)

### BRIEF DESCRIPTION OF THE DRAWINGS

FIG. 1 is a top view showing an example of a semiconductor device 100 according to one embodiment of the present invention.

FIG. 2 shows an example of an equivalent circuit to the semiconductor device 100.

FIG. 3 is a cross-sectional view showing an example of a control element provided in a control circuit unit 200.

FIG. 4 is a cross-sectional view showing another example of a control element provided in a control circuit unit 200.

FIG. 5 is a cross-sectional view showing another example of a control element provided in a control circuit unit 200.

FIG. 6 is a cross-sectional view showing an example of a power element unit 10.

FIG. 7 is a cross-sectional view showing another example of a power element unit 10.

FIG. 8 is a cross-sectional view showing another example of a MOSFET 202.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

Unless otherwise stated, SI unit system is used as unit system herein. Although a unit of length may be expressed in cm, calculations may be carried out after conversion to meters (m). In the present specification, one side of a direction parallel to a depth direction of a semiconductor substrate is referred to as “upper”, and the other side is referred to as “lower”. One of two main surfaces of a substrate, a layer, or other members is referred to as an “upper surface”, and the other surface is referred to as a “lower surface”. “Upper” and “lower” directions are not limited to a direction of gravity, or a direction in which a semiconductor device is mounted.

As used herein, technical matters may be described with orthogonal coordinate axes consisting of an X axis, a Y axis, and a Z axis. The orthogonal coordinate axes are merely for specifying relative positions of components, and are thus not for limiting to a specific direction. For example, the Z axis is not limited to represent a height direction with respect to the ground. Note that a +Z axis direction and a −Z axis direction are directions opposite to each other. When a direction is referred to as a “Z axis direction” without these “−F” and “−” signs, it means the Z axis direction is parallel to +Z and −Z axes.

In the present specification, orthogonal axes parallel to an upper surface and lower surface of a semiconductor substrate are referred to as the X axis and the Y axis. Further, an axis perpendicular to the upper surface and the lower surface of the semiconductor substrate is referred to as the Z axis. As used herein, a direction of the Z axis may be referred to as a depth direction. Further, in the present specification, a direction parallel to the upper surface and the lower surface of the semiconductor substrate may be referred to as a horizontal direction, including the X axis direction and the Y axis direction. In the present specification, an upper surface side of the semiconductor substrate refers to a region from the center to the upper surface of the semiconductor substrate in the depth direction. A lower surface side of the semiconductor substrate refers to a region from the center to the lower surface of the semiconductor substrate in the depth direction.

As used herein, phrases such as “same” or “equal” may be used even when there is an error caused due to a variation in a fabrication step or the like. This error is within a range of 10% or less, for example. Descriptions of directions herein with the wording “perpendicular,” “parallel,” or “along” may indicate a situation with an error caused by, for example, variations in a fabrication step. For example, the error may be 5° or smaller.

In the present specification, a conductivity type of a doped region where doping has been carried out with an impurity is described as a P type or an N type. The N type is an example of a first conductivity type. The P type is an example of a second conductivity type. In the present specification, doping means introducing the donor or the acceptor into the semiconductor substrate and turning it into a semiconductor showing a conductivity type of the N type, or a semiconductor showing a conductivity type of the P type. Reference to a P+ type or an N+ type herein means that a doping concentration is high in comparison with the P type or the N type.

Reference to a P− type or an N− type herein means that a doping concentration is low in comparison with the P type or the N type. Regions of the N−, N, and N+ types, which have different concentrations, may be collectively referred to as regions of the N type herein. Regions of the P−, P, and P+ types, which have different concentrations, may be collectively referred to as regions of the P type herein.

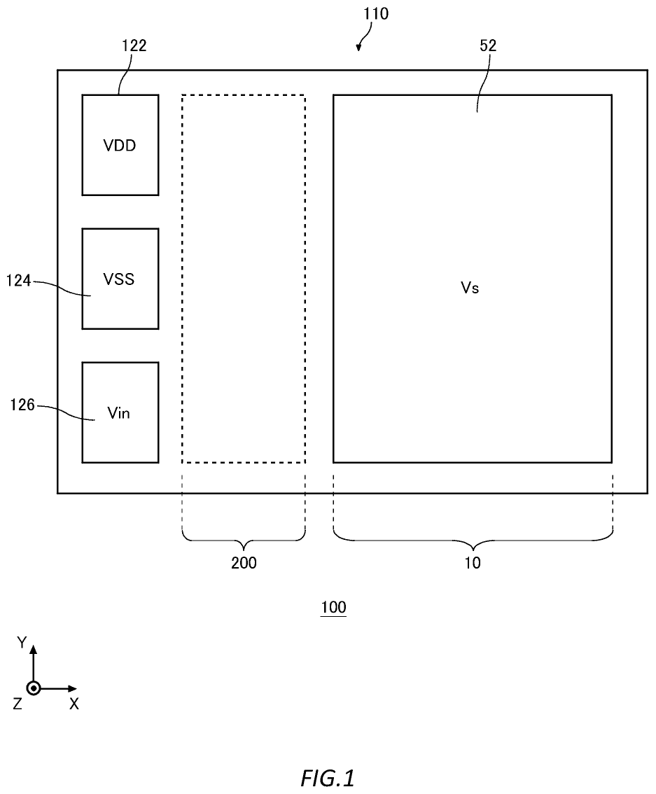

FIG. 1 is a top view showing an example of a semiconductor device 100 according to one embodiment of the present invention. The semiconductor device 100 is a semiconductor chip in which a transistor element such as a MOSFET is formed. The semiconductor device 100 includes a semiconductor substrate 110 in which transistor elements are formed. The semiconductor substrate 110 in this example contains silicon carbide (SiC). As an example, the semiconductor substrate 110 is a silicon carbide substrate formed from silicon carbide and minute impurities. FIG. 1 depicts the region of a portion of the upper surface of the semiconductor substrate 110. In FIG. 1, the positions of some members of the semiconductor device 100 are projected onto the upper surface of the semiconductor substrate 110. Performing observation with the positions of individual members being projected onto a plane parallel to the upper surface of the semiconductor substrate 110 may be referred to as seeing in a top view herein.

The semiconductor device 100 includes a control circuit unit 200 formed in the semiconductor substrate 110. The control circuit unit 200 includes one or more control elements. The control circuit unit 200 may include a plurality of control elements. At least one control element is a lateral MOSFET formed in the upper surface of the semiconductor substrate 110. The lateral MOSFET includes a source region and a drain region disposed in the same surface (e.g., upper surface) of the semiconductor substrate 110. The control circuit unit 200 may include a P-channel MOSFET, an N-channel MOSFET, or a CMOSFET as a control element.

The semiconductor device 100 may include a plurality of pads connected to the control circuit unit 200. Each pad may be formed from a metal material of, for example, aluminum. The semiconductor device 100 in this example includes a VDD pad 122, a VSS pad 124, and a signal pad 126, which are disposed above the semiconductor substrate 110. A power supply voltage VDD is applied to the VDD pad 122. A reference voltage VSS is applied to the VSS pad 124. The reference voltage VSS may be a ground potential or another potential. An input signal Vin is applied to the signal pad 126. For example, the input signal Vin is applied to a gate terminal of the MOSFET included in the control circuit unit 200.

The semiconductor device 100 may further include a power element unit 10 formed in the semiconductor substrate 110. The power element unit 10 may include a vertical MOSFET. The vertical MOSFET includes a source region and a drain region disposed in different surfaces (upper and lower surfaces with reference to this example) of the semiconductor substrate 110. The power element unit 10 controls whether to allow a current to flow between the upper and lower surfaces of the semiconductor substrate 110. A source pad 52 is disposed above the power element unit 10 in this example.

The control circuit unit 200 in this example controls operations of the power element unit 10. The control circuit unit 200 may control whether to turn on or off the vertical MOSFET provided in the power element unit 10. In response to the input signal Vin, the control circuit unit 200 in this example outputs an output signal for controlling the power element unit 10.

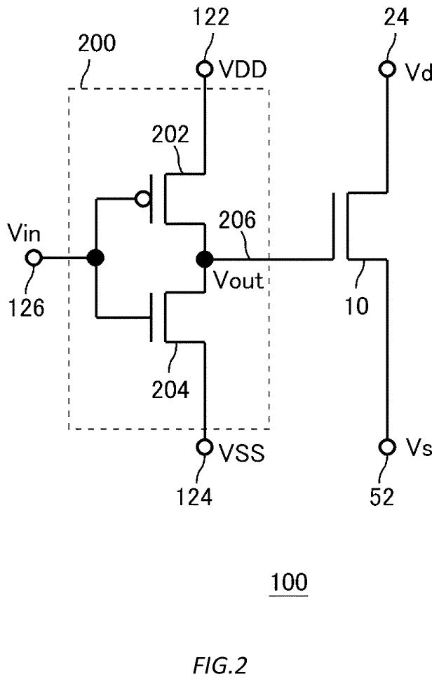

FIG. 2 shows an example of an equivalent circuit to the semiconductor device 100. The power element unit 10 in this example is a vertical MOSFET. Although FIG. 2 depicts one vertical MOSFET, the power element unit 10 may be provided with a plurality of vertical MOSFETs. The vertical MOSFET is connected between a drain pad 24 and a source pad 52.

The control circuit unit 200 in this example includes one or more CMOSFETs. Although FIG. 2 depicts one CMOSFET, the control circuit unit 200 may be provided with a plurality of CMOSFETs. The CMOSFET includes a P-channel MOSFET 202 and an N-channel MOSFET 204.

The MOSFET 202 is connected between a VDD pad 122 and an output terminal 206. The output terminal 206 applies an output voltage Vout to the gate terminal of the MOSFET of the power element unit 10.

The MOSFET 204 is connected between the output terminal 206 and a VSS pad 124. The same input signal Vin is applied to the MOSFETs 202 and 204. Thus, the MOSFETs 202 and 204 are operated complementarily with each other and output an output signal Vout corresponding to the input signal Vin.

A drive current output by the control circuit unit 200 charges the gate capacitance of the power element unit 10. Thus, the control circuit unit 200 preferably outputs a drive current with which the gate capacitance of the power element unit 10 can be charged at a sufficiently high speed. However, attempting to increase a drive current to be output by the control circuit unit 200 would increase the area occupied by the control circuit unit 200 within the semiconductor substrate 110. If the MOSFETs 202 and 204 of the control circuit unit 200 include a planar gate, it will be difficult to decrease the area of the control circuit unit 200.

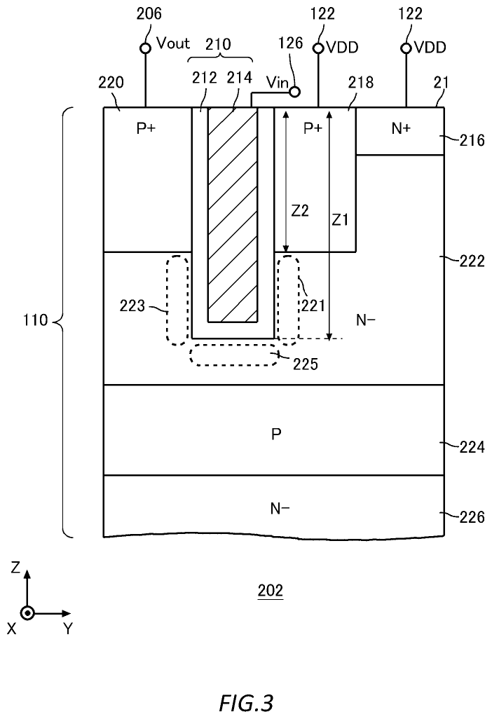

FIG. 3 is a cross-sectional view showing an example of a control element provided in the control circuit unit 200. The cross section is a YZ plane perpendicular to an upper surface 21 of a semiconductor substrate 110. FIG. 3 depicts a P-channel MOSFET 202 as the control element. The MOSFET 202 is an example of a second control element.

The MOSFET 202 includes a P+ type source region 218, a P+ type drain region 220, an N-type base region 222, and a gate trench section 210. The MOSFET 202 may further include at least one of an N+ type source region 216, a P type high concentration region 224, and an N− type drift region 226.

The source region 218 is an example of a control source region. The source region 218 is provided to be exposed on the upper surface 21 of the semiconductor substrate 110. A power supply voltage VDD is applied to the source region 218 from a VDD pad 122.

The drain region 220 is provided to be exposed on the upper surface 21 of the semiconductor substrate 110. The drain region 220 is an example of a control drain region of the same conductivity type as the control source region (source region 218 with reference to this example). The drain region 220 outputs an output signal Vout to an output terminal 206.

The base region 222 is an example of a control base region of a different conductivity type from the control source region (source region 218 with reference to this example). The base region 222 is provided in contact with the source region 218. The base region 222 may be connected to the VDD pad 122 via the source region 216.

The source region 216 is an N+ type region provided to be exposed on the upper surface 21 of the semiconductor substrate 110 and having a higher doping concentration than the base region 222. The source region 216 may apply the power supply voltage VDD to the base region 222.

The gate trench section 210 is an example of a control gate trench section. The gate trench section 210 is provided from the upper surface 21 of the semiconductor substrate 110 to an internal portion of the semiconductor substrate 110 and being in contact with the base region 222. The gate trench section 210 includes a gate insulating film 212 and a gate electrode 214. The gate insulating film 212 covers an inner wall of the gate trench section 210, which is shaped like a groove. For example, the gate insulating film 212 is formed by oxidizing or nitriding the inner wall of the gate trench section 210.

The gate insulating film 212 surrounds the gate electrode 214. The gate insulating film 212 electrically insulates the gate electrode 214 from the semiconductor substrate 110. An input signal Vin is applied to the gate electrode 214 from a signal pad 126. For example, the gate electrode 214 is formed by depositing polysilicon doped with impurities within a region surrounded by the gate insulating film 212.

Each member depicted within the YZ cross section of each figure may be provided to extend in an X axis direction. For example, the gate trench section 210 is provided to extend in the X axis direction. The gate trench section 210 in this example is disposed between the source region 218 and the drain region 220 in the X axis direction. The gate trench section 210 may or may not be in contact with the source region 218 and the drain region 220. The source region 218 and the drain region 220 may also be provided to extend in the X axis direction along the gate trench section 210.

The base region 222 includes a portion that is along the gate trench section 210 from the source region 218 to the drain region 220. The base region 222 in this example includes a portion 221, a portion 223, and a portion 225. The portion 221 extends in contact with a side wall of the gate trench section 210 from a position at which this portion is in contact with the source region 218 to a lower end of the gate trench section 210. The portion 223 extends in contact with a side wall of the gate trench section 210 from a position at which this portion is in contact with the drain region 220 to the lower end of the gate trench section 210. The portion 225 extends in contact with a lower face of the gate trench section 210 from the portion 221 to the portion 223.

Applying a prescribed on voltage to the gate electrode 214 causes a P type channel to be formed in a surface layer of the portions 221, 223, and 225 that is in contact with the gate trench section 210. As a result, the source region 218 and the drain region 220 are electrically connected. A face of the semiconductor substrate 110 that is in contact with a side face of the gate trench section 210 may be an m-face. That is, an XZ cross section of the semiconductor substrate 110 may be the m-face. Accordingly, the carrier mobility at the portions 221 and 223 can be enhanced.

Let Z1 be the distance between the upper surface 21 of the semiconductor substrate 110 and the lower end of the gate trench section 210 in a Z axis direction. Let Z2 be the distance between the upper surface 21 of the semiconductor substrate 110 and the lower end of the source region 218 in the Z axis direction. Z2 may also be the distance between the upper surface 21 of the semiconductor substrate 110 and the lower end of the drain region 220 in the Z axis direction. The distance Z1 is greater than the distance Z2. The distance Z2 may be at least half the distance Z1. Increasing the distance Z2 allows the length of the portions 221 and 223 in the Z axis direction to be decreased. In this way, the channel can be shortened. The distance Z2 may be at least ¾ of the distance Z1.

The high concentration region 224 is disposed to face the lower end of the gate trench section 210 in the depth direction of the semiconductor substrate 110 (Z axis direction). The high concentration region 224 is an example of a control high concentration region. The high concentration region 224 in this example is disposed apart from the gate trench section 210. The high concentration region 224 may be provided below the source region 218, the drain region 220, the base region 222, and the gate trench section 210. The high concentration region 224 may be disposed to overlap the entirety of the MOSFET 202 depicted in FIG. 3. Providing the high concentration region 224 allows the MOSFET 202 to be isolated from the drift region 226. A power element unit 10 is also provided with the drift region 226, which is shared with the control circuit unit 200. Thus, providing the high concentration region 224 allows the MOSFET 202 and the power element unit 10 to be isolated from each other.

The drift region 226 is provided between the high concentration region 224 and the lower surface of the semiconductor substrate 110. The entirety of the semiconductor substrate 110 may be an N− type substrate before a locally doped region such as the source region 218 is formed. The drift region 226 may be a residual region in which no locally doped regions are formed. The base region 222 may be the drift region 226 or a doped region locally formed. That is, the base region 222 may have the same doping concentration as, or a different doping concentration from, the drift region 226.

Providing, as depicted in FIG. 3, the gate trench section 210 allows channels to be formed in the control circuit unit 200 in the depth direction of the semiconductor substrate 110. Thus, many channels can be formed in a top view of the control circuit unit 200, and the channel width and the channel density in the top view can be easily increased. Accordingly, the drive current output by the control circuit unit 200 can be easily increased.

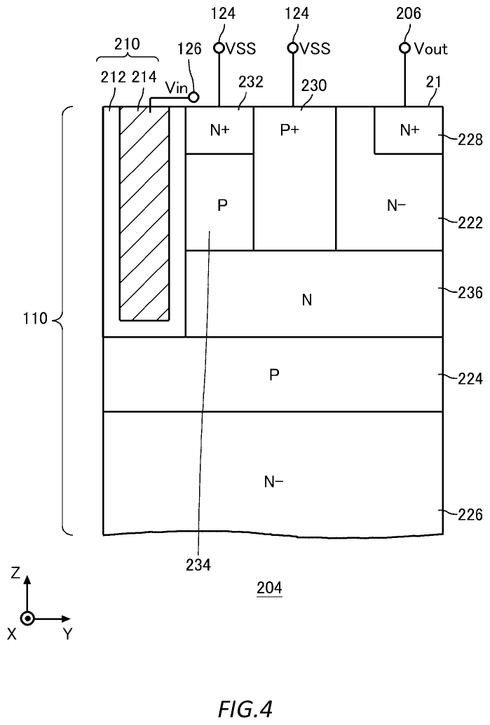

FIG. 4 is a cross-sectional view showing another example of a control element provided in a control circuit unit 200. The cross section is a YZ plane perpendicular to an upper surface 21 of a semiconductor substrate 110. FIG. 4 depicts an N-channel MOSFET 204 as the control element. The MOSFET 204 is an example of a first control element.

The MOSFET 204 includes an N+ type source region 232, an N+ type drain region 228, a P type base region 234, and a gate trench section 210. The MOSFET 204 may further include at least one of a P+ type source region 230, a P type high concentration region 224, an N− type base region 222, an N type resistance reduction region 236, and an N− type drift region 226.

The source region 232 is an example of a control source region provided to be exposed on the upper surface 21 of the semiconductor substrate 110. A reference voltage VSS is applied to the source region 232 from a VSS pad 124.

The drain region 228 is provided to be exposed on the upper surface 21 of the semiconductor substrate 110. The drain region 228 is an example of a control drain region of the same conductivity type as the control source region (source region 232 with reference to this example). The drain region 228 outputs an output signal Vout to an output terminal 206. The drain region 228 may be connected to a drain region 220 of a MOSFET 202.

The base region 234 is an example of a control base region of a different conductivity type from the control source region (source region 232 with reference to this example). The base region 234 is provided in contact with the source region 232. The base region 234 may be connected to the VSS pad 124 via the source region 230.

The source region 230 may be provided to be exposed on the upper surface 21 of the semiconductor substrate 110. The source region 230 may apply the reference voltage VSS to the base region 234.

The gate trench section 210 is an example of a control gate trench section in contact with the control base region (base region 234 with reference to this example). The gate trench section 210 is provided from the upper surface 21 of the semiconductor substrate 110 to an internal portion of the semiconductor substrate 110. The gate trench section 210 may have the same structure as the gate trench section 210 shown in FIG. 3.

The semiconductor substrate 110 is provided with an N type control drift region connecting the base region 234 to the drain region 228. In this example, the resistance reduction region 236 and the base region 222 are an example of the control drift region. The base region 222 is connected to the drain region 228. The doping concentration of the base region 222 may be the same as the doping concentration of the base region 222 shown in FIG. 3.

The resistance reduction region 236 connects the base region 234 to the base region 222. The resistance reduction region 236 is an N type region having a higher doping concentration than the base region 222. Providing the resistance reduction region 236 allows for a reduction in electric resistance at a current path from the base region 234 to the drain region 228. In another example, the base region 222 may be connected to the base region 234 without the resistance reduction region 236 being provided.

The gate trench section 210 in this example is in contact with the base region 234, from the boundary between the source region 232 and the base region 234 to the boundary between the resistance reduction region 236 and the base region 234. Applying a prescribed on voltage to the gate electrode 214 causes an N type channel to be formed in a surface layer of the base region 234 that is in contact with the gate trench section 210. As a result, the source region 232 and the resistance reduction region 236 are electrically connected, and the source region 232 and the drain region 228 are electrically connected.

The resistance reduction region 236 may be provided to extend, in a direction away from the gate trench section 210 (Y axis direction), from a position at which this region is in contact with the lower end of the base region 234. The resistance reduction region 236 may extend from a position below the base region 234 to a position below the drain region 228. The resistance reduction region 236 may extend in the Y axis direction so as to pass a position below the source region 230. The source region 230 may or may not be in contact with the resistance reduction region 236. The base region 234 may be disposed between the source region 230 and the resistance reduction region 236. The base region 222 may be disposed between the drain region 228 and the resistance reduction region 236 in the Z axis direction.

Also in the MOSFET 204, the high concentration region 224 is disposed to face the lower end of the gate trench section 210 in the depth direction of the semiconductor substrate 110 (Z axis direction). In the MOSFET 204, the high concentration region 224 may be in contact with the lower end of the gate trench section 210, or may be disposed apart from the gate trench section 210. The high concentration region 224 may be provided below the source region 232, the drain region 228, the base region 234, and the gate trench section 210. The high concentration region 224 may be disposed to overlap the entirety of the MOSFET 204 depicted in FIG. 4. Providing the high concentration region 224 allows the MOSFET 204 and the power element unit 10 to be isolated from each other. The drift region 226 is provided between the high concentration region 224 and the lower surface of the semiconductor substrate 110.

Providing, as depicted in FIG. 4, the gate trench section 210 allows a channel to be formed in the control circuit unit 200 in the depth direction of the semiconductor substrate 110. Thus, the channel width and the channel density in the control circuit unit 200 can be easily increased, and the drive current output by the control circuit unit 200 can be easily increased.

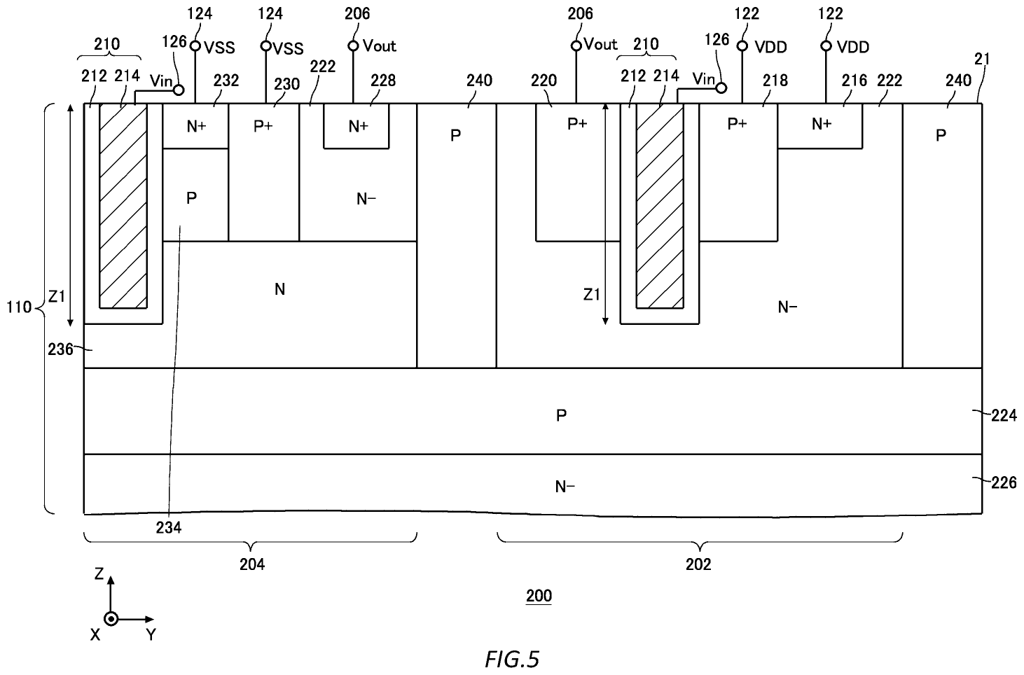

FIG. 5 is a cross-sectional view showing another example of a control element provided in a control circuit unit 200. The control circuit unit 200 in this example includes a MOSFET 202 and a MOSFET 204. The MOSFET 202 has a similar structure to the MOSFET 202 depicted in FIG. 3. The MOSFET 204 has a similar structure to the MOSFET 204 depicted in FIG. 4.

The control circuit unit 200 in this example includes an isolation region 240. The isolation region 240 isolates the MOSFET 202 from other elements and isolates the MOSFET 204 from other elements. The isolation region 240 is a P type region. The isolation region 240 may have the same doping concentration as, or a different doping concentration from, high concentration regions 224. The isolation region 240 may have the same doping concentration as a source region 218, a drain region 220, or a source region 230.

The isolation region 240 may be provided from an upper surface 21 of a semiconductor substrate 110 to the high concentration regions 224. The isolation region 240 may be disposed between the MOSFETs 202 and 204. The isolation region 240 in this example surrounds each of the MOSFETs 202 and 204 when seen in a top view. Providing the isolation region 240 allows each of the MOSFETs 202 and 204 to be isolated from other elements. A reference voltage VSS may be applied to the isolation region 240.

In this example, the high concentration region 224 of the MOSFET 202 and the high concentration region 224 of the MOSFET 204 are provided at the same depth position. A gate trench section 210 of the MOSFET 202 and a gate trench section 210 of the MOSFET 204 are provided to extend to the same depth. Thus, the control circuit unit 200 can formed through a simple fabrication process. In the MOSFET 202, the gate trench section 210 is disposed apart from the high concentration region 224. In the MOSFET 204 in this example, accordingly, the gate trench section 210 is disposed apart from the high concentration region 224.

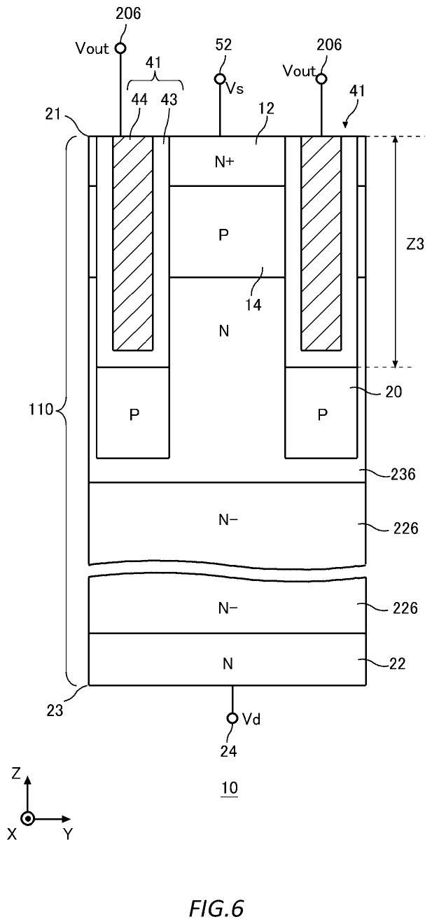

FIG. 6 is a cross-sectional view showing an example of a power element unit 10. The cross section is a YZ plane perpendicular to an upper surface 21 of a semiconductor substrate 110. The power element unit 10 in this example includes an N− type drift region 226 disposed between the upper surface 21 and lower surface 23 of the semiconductor substrate 110. The drift region 226 of the power element unit 10 is continuous with a drift region 226 of a control circuit unit 200. A P type isolation region 240 may be provided between the power element unit 10 and the control circuit unit 200. The P type isolation region 240 may be in contact with a high concentration region 224.

The power element unit 10 may include a resistance reduction region 236 disposed above the drift region 226 and having a higher doping concentration than the drift region 226. The drift region 226 and the resistance reduction region 236 are an example of a power drift region. The resistance reduction region 236 may have the same doping concentration as, or a different doping concentration from, a resistance reduction region 236 of the control circuit unit 200.

The power element unit 10 is provided with an N+ type source region 12 having a higher doping concentration than the drift region 226 and located between the drift region 226 and the upper surface 21 of the semiconductor substrate 110. The source region 12 is an example of a power source region provided in the upper surface 21 of the semiconductor substrate 110. The source region 12 is connected to a source pad 52, and a source voltage Vs is applied to this region.

A P type base region 14 is provided between the source region 12 and the drift region 226. The base region 14 is an example of a power base region of a different conductivity type from the power source region (source region 12 with reference to this example). The base region 14 is provided below the source region 12.

A resistance reduction region 236 may be provided between the base region 14 and the drift region 226. Providing the resistance reduction region 236 allows for a reduction in the resistance of a path through which a main current flows.

An N type drain region 22 having a higher doping concentration than the drift region 226 may be provided between the drift region 226 and the lower surface 23. The drain region 22 is an example of a power drain region of the same conductivity type as the power source region (source region 12). The drain region 22 is provided in the lower surface 23 of the semiconductor substrate 110. The drain region 22 is connected to a drain pad 24, and a drain voltage Vd is applied to this region. The drift region 226 is an example of a power drift region of the same conductivity type as the power source region (source region 12). The drift region 226 is provided between the base region 14 and the drain region 22. The drain region 22 is connected to the drain pad 24. In another example, without the semiconductor substrate 110 being provided with the drain region 22, a region including the lower edge of the drift region 226 may function as a drain region 22.

A plurality of gate trench sections 41 are provided in the upper surface 21 of the semiconductor substrate 110. Each of the gate trench sections 41 is provided from the upper surface 21 of the semiconductor substrate 110 to a position below the base region 14 and reaches the power drift region. The gate trench sections 41 in this example are provided to extend to such a depth as to reach the resistance reduction region 236. When the resistance reduction region 236 is not provided, the gate trench sections 41 may be provided to extend to such a depth as to reach the drift region 226. The gate trench sections 41 are an example of a power gate (registered trademark) trench section in contact with the power base region (base region 14).

With reference to the YZ cross section, the gate trench sections 41 may have the same structure as the gate trench sections 210 of the control circuit unit 200. A length Z3 of the gate trench sections 41 in the depth direction may be the same as or different from the length Z1 of the gate trench sections 210 in the depth direction.

The gate trench sections 41 each include a gate insulating film 43 and a gate electrode 44. The gate insulating films 43 cover inner walls of the gate trench sections 41, which are shaped like grooves. For example, the gate insulating films 43 are formed by oxidizing or nitriding the inner walls of the gate trench sections 41. The gate insulating films 43 may each be formed by depositing a silicon oxide film or a silicon nitride film.

The gate insulating films 43 surround the gate electrodes 44. The gate insulating films 43 electrically insulate the gate electrodes 44 from the semiconductor substrate 110. An output signal Vout is applied to the gate electrodes 44 from the output terminals 206 of the control circuit unit 200. For example, the gate electrodes 44 are each formed by depositing polysilicon doped with impurities within a region surrounded by the gate insulating film 43.

Applying a prescribed on voltage to the gate electrodes 44 causes N type channels to be formed in surface layers of the base region 14 that are in contact with the gate trench section 41. As a result, the source region 12 and the drain region 22 are electrically connected.

The semiconductor substrate 110 may be provided with P type high concentration regions 20 disposed to face the lower ends of the gate trench sections 41 in the Z axis direction. The high concentration regions 20 are an example of a power high concentration region.

The high concentration regions 20 in this example are in contact with the lower ends of the gate trench sections 41. Neither of the high concentration regions 20 are provided in at least portions of the region below the base region 14. The high concentration regions 20 may be provided within a range that is less deep than the lower edge of the resistance reduction region 236, or may be in contact with the drift region 226. Providing the high concentration regions 20 allows a concentration of electric fields in the vicinity of the lower edge of each of the gate trench sections 41 to be alleviated such that the pressure resistance of the power element unit 10 can be increased.

The high concentration regions 20 may be disposed at the same positions in the depth direction as the high concentration regions 224 of the control circuit unit 200. The high concentration regions 20 may have the same doping concentration as the high concentration regions 224. In this way, the high concentration regions 20 and the high concentration regions 224 can be formed in the same fabrication process. In another example, the high concentration regions 20 may be provided at a different depth position from the high concentration regions 224. The high concentration regions 20 may have a different doping concentration from the high concentration regions 224.

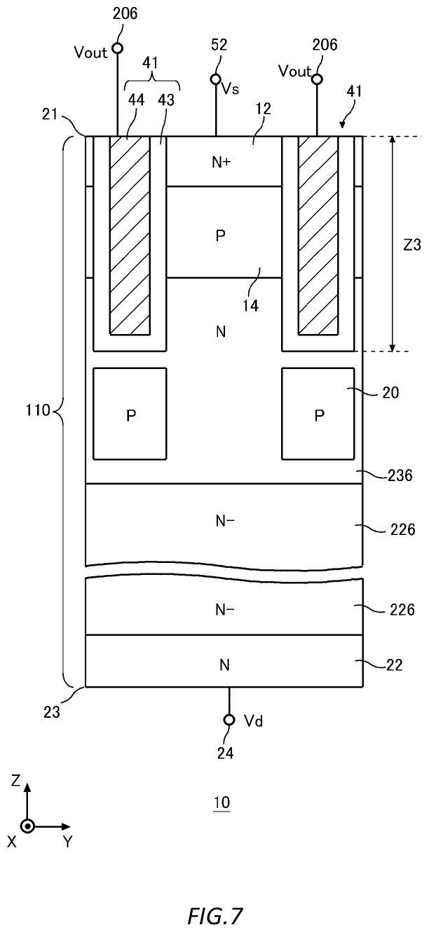

FIG. 7 is a cross-sectional view showing another example of a power element unit 10. The power element unit 10 in this example differs from the example of FIG. 6 in that high concentration regions 20 are spaced apart from the lower ends of gate trench sections 41. Otherwise, the power element unit 10 in this example is the same as the example of FIG. 6.

In this example, the length Z3 of the gate trench sections 41 of the power element unit 10 is the same as the length Z1 of the gate trench sections 210 of the control circuit unit 200. The depth position of the high concentration regions 20 of the power element unit 10 is the same as the depth position of the high concentration regions 224 of the control circuit unit 200. Owing to such a structure, the power element units 10 and the control circuit units 200 can be fabricated in a common fabrication process.

As described above, the high concentration region 224 of the MOSFET 202 is disposed apart from the lower end of the gate trench section 210. In the MOSFET 204, accordingly, the high concentration region 224 is also disposed apart from the lower end of the gate trench section 210. Similarly, the high concentration regions 20 of the power element unit 10 are disposed apart from the lower ends of the gate trench sections 41. Also in such a structure, the high concentration regions 20 are disposed in the vicinities of the lower ends of the gate trench sections 41, so that a concentration of electric fields in the vicinity of the lower end of each of the gate trench sections 41 can be alleviated. The high concentration regions 20 may be provided above the lower edge of the resistance reduction region 236.

In another example, the high concentration regions 20 are, as depicted in FIG. 6, in contact with the lower ends of the gate trench sections 41, and the high concentration region 224 of the MOSFET 202 may be disposed apart from the lower end of the gate trench section 210. In this way, a concentration of electric fields in the vicinity of the lower end of each of the gate trench sections 41 can be alleviated more effectively. The high concentration region 224 of the MOSFET 204 may be in contact with, or spaced apart from, the lower end of the gate trench section 210.

In this case, the length Z1 of the gate trench section 210 of the MOSFET 202 may be less than the length Z3 of the gate trench sections 41 of the power element unit 10. The length of the gate trench section 210 of the MOSFET 204 may be the same as the length Z3 of the gate trench sections 41 of the power element unit 10. The high concentration regions 20 and 224 may be formed at the same depth position. In this way, the high concentration regions 20 may be disposed in contact with the lower ends of the gate trench sections 41, and the high concentration region 224 of the MOSFET 202 may be disposed apart from the lower end of the gate trench section 210. The high concentration region 224 of the MOSFET 204 may be disposed in contact with the lower end of the gate trench section 210. In another example, the gate trench sections 210 and 41 may be the same in length such that the depth positions of the high concentration regions 20 and 224 are different.

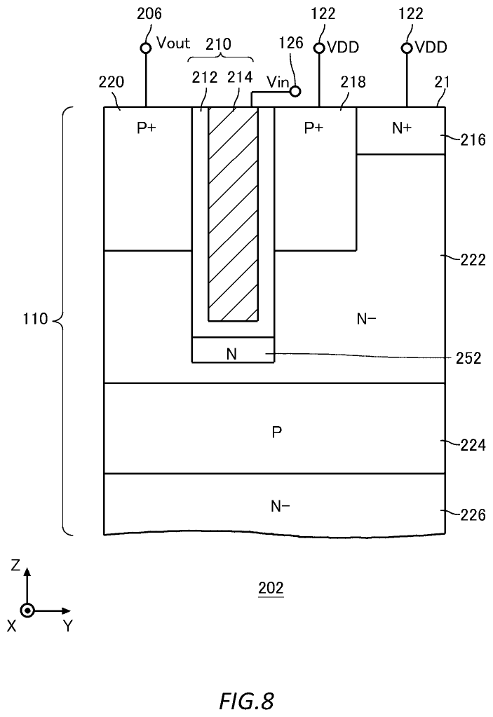

FIG. 8 is a cross-sectional view showing another example of a MOSFET 202. The MOSFET 202 in this example differs from the examples described above by referring to FIG. 3-7 in that this MOSFET includes an inversion prevention region 252. Otherwise, the MOSFET 202 in this example is the same as any of the examples described above by referring to FIG. 3-7.

The inversion prevention region 252 is an N type region provided in contact with the lower end of a gate trench section 210 and having a higher concentration than a base region 222. The inversion prevention region 252 may cover the entirety of the lower face of the gate trench section 210. Such a structure allows the region in contact with the lower end of the gate trench section 210 to be prevented from being inverted into a P type. Thus, it is possible to suppress a channel from being unintentionally formed between a source region 218 and a drain region 220. Moreover, providing the inversion prevention region 252 allows a threshold voltage of the MOSFET 202 to be adjusted.

In each of the examples described above by referring to FIG. 1-8, the gate trench sections 41 of the power element unit 10 and the gate trench sections 210 of the control circuit unit 200 are both provided to extend in the X axis direction. In other examples, when seen in a top view, the gate trench sections 41 of the power element unit 10 may extend in a different direction from the gate trench sections 210 of the control circuit unit 200.

While the present invention has been described by way of the embodiments, the technical scope of the present invention is not limited to the above described embodiments. It is apparent to persons skilled in the art that various alterations or improvements can be made to the above described embodiments. It is also apparent from the claim recitations that embodiments added with such alterations or improvements can be included in the technical scope of the present invention.

What is claimed is:

1. A semiconductor device comprising:
a semiconductor substrate including an upper surface and a lower surface and containing silicon carbide; and
a control circuit unit formed in the semiconductor substrate and including one or more control elements, wherein
the one or more control elements each include:
a control source region provided in the upper surface of the semiconductor substrate;
a control drain region provided in the upper surface of the semiconductor substrate and being of a same conductivity type as the control source region;
a control base region provided in contact with the control source region and being of a different conductivity type from the control source region; and
a control gate trench section provided from the upper surface of the semiconductor substrate to an internal portion of the semiconductor substrate and being in contact with the control base region.

2. The semiconductor device according to claim 1, further comprising:
a power element unit that is formed in the semiconductor substrate and controls whether to cause a current to flow between the upper surface and the lower surface of the semiconductor substrate, wherein
the power element unit includes:
a power source region provided in the upper surface of the semiconductor substrate;
a power drain region provided in the lower surface of the semiconductor substrate and being of a same conductivity type as the power source region;
a power base region provided below the power source region and being of a different conductivity type from the power source region;
a power drift region provided between the power base region and the power drain region and being of a same conductivity type as the power source region; and
a power gate trench section provided from the upper surface of the semiconductor substrate to such a depth as to reach the power drift region and being in contact with the power base region, and
the control circuit unit controls an operation of the power element unit.

3. The semiconductor device according to claim 1, wherein
the one or more control elements include a first control element,
in the first control element,
the control source region and the control drain region are N type regions,
the control base region is a P type region provided below the control source region,
an N type control drift region that connects the control base region to the control drain region is provided, and
the control gate trench section is in contact with the control base region, from a boundary between the control source region and the control base region to a boundary between the control drift region and the control base region.

4. The semiconductor device according to claim 1, wherein
the one or more control elements include a second control element,
in the second control element,
the control source region and the control drain region are P type regions,
the control gate trench section is disposed between the control source region and the control drain region, and
the control base region is, from the control source region to the control drain region, an N type region which includes a portion that is along the control gate trench section.

5. The semiconductor device according to claim 1, further comprising:
a P type isolation region surrounding the one or more control elements when the semiconductor substrate is seen in a top view.

6. The semiconductor device according to claim 2, further comprising:
a P type isolation region between the one or more control elements and the power element unit.

7. The semiconductor device according to claim 2, further comprising:
a P type control high concentration region disposed to face a lower end of the control gate trench section in a depth direction of the semiconductor substrate.

8. The semiconductor device according to claim 7, wherein
the control high concentration region is in contact with the lower end of the control gate trench section.

9. The semiconductor device according to claim 7, further comprising:
a P type power high concentration region disposed to face a lower end of the power gate trench section in the depth direction.

10. The semiconductor device according to claim 9, wherein
the control high concentration region and the power high concentration region are provided at a same position in the depth direction.

11. The semiconductor device according to claim 10, wherein
the control source region and the control drain region are P type regions, and
the control gate trench section is disposed between the control source region and the control drain region, shorter than the power gate trench section in the depth direction, and disposed apart from the control high concentration region.

12. The semiconductor device according to claim 10, wherein
the power high concentration region is disposed apart from the power gate trench section.

13. The semiconductor device according to claim 7, further comprising:
an N type inversion prevention region provided in contact with the lower end of the control gate trench section and having a higher concentration than the control base region.

14. The semiconductor device according to claim 1, wherein
the one or more control elements include a first control element and a second control element,
in the first control element,
the control source region and the control drain region are N type regions,
the control base region is a P type region provided below the control source region,
an N type control drift region that connects the control base region to the control drain region is provided, and
the control gate trench section is, from a boundary between the control source region and the control base region to a boundary between the control drift region and the control base region, in contact with the control base region, and
in the second control element,
the control source region and the control drain region are P type regions, and
the control gate trench section is disposed between the control source region and the control drain region, and
the control base region is, from the control source region to the control drain region, an N type region which includes a portion that is along the control gate trench section.

15. The semiconductor device according to claim 2, wherein
the one or more control elements include a first control element,
in the first control element,
the control source region and the control drain region are N type regions,
the control base region is a P type region provided below the control source region,
an N type control drift region that connects the control base region to the control drain region is provided, and
the control gate trench section is in contact with the control base region, from a boundary between the control source region and the control base region to a boundary between the control drift region and the control base region.

16. The semiconductor device according to claim 2, wherein
the one or more control elements include a second control element,
in the second control element,
the control source region and the control drain region are P type regions,
the control gate trench section is disposed between the control source region and the control drain region, and
the control base region is, from the control source region to the control drain region, an N type region which includes a portion that is along the control gate trench section.

17. The semiconductor device according to claim 2, wherein
the one or more control elements include a first control element and a second control element,
in the first control element,
the control source region and the control drain region are N type regions,
the control base region is a P type region provided below the control source region,
an N type control drift region that connects the control base region to the control drain region is provided, and
the control gate trench section is, from a boundary between the control source region and the control base region to a boundary between the control drift region and the control base region, in contact with the control base region, and
in the second control element,
the control source region and the control drain region are P type regions,
the control gate trench section is disposed between the control source region and the control drain region, and
the control base region is an N type region including a portion extending along the control gate trench section from the control source region to the control drain region.
